(19) United States
(12) Patent Application Publication
(10) Pub. No.: US 2008/0315285 A1
(43) Pub. Date: Dec. 25, 2008

(54) Non-volatile memory devices and methods of fabricating the same

(75) Inventors: Tae-hee Lee, Yongin-si (KR); Jae-woong Hyun, Uijeongbu-si (KR); Ju-hee Park, Guri-si (KR); In-kyeong Yoo, Suwon-si (KR); Yoon-dong Park, Yongin-si (KR); Won-joo Kim, Hwaseong-si (KR); Jung-hoon Lee, Seoul (KR)

Correspondence Address: HARNESS, DICKEY & PIERCE, P.L.C., P.O. BOX 8910, RESTON, VA, 20195, US

(73) Assignee: Samsung Electronics Co., Ltd.

(21) Appl. No.: 12/071,452

(22) Filed: Feb. 21, 2008

(30) Foreign Application Priority Data
Jun. 19, 2007 (KR) 10-2007-0060051

(51) Int. Cl. H01L 29/788; H01L 21/336

(52) U.S. Cl. 257/316; 438/264; 257/E29.3; 257/E21.409

(57) ABSTRACT

Non-volatile memory devices and methods of fabricating the same are provided. The non-volatile memory devices may include a semiconductor substrate having a pair of sidewall channel regions extending from the semiconductor substrate and opposite to each other, and a floating gate electrode between the pair of sidewall channel regions and protruding from the semiconductor substrate. A control gate electrode may be formed on the semiconductor substrate and a portion of the floating gate electrode.

### PRIORITY STATEMENT

This application claims the benefit of priority under 35 U.S.C. §119 from Korean Patent Application No. 10-2007-0060051, filed on Jun. 19, 2007, in the Korean Intellectual Property Office, the disclosure of which is incorporated herein in its entirety by reference.

### BACKGROUND

1. Field

Example embodiments relate to semiconductor devices and methods of fabricating the same. Other example embodiments relate to non-volatile memory devices for storing data and methods of fabricating the same.

2. Description of the Related Art

Non-volatile memory devices including an electrically erasable programmable read-only memory (EEPROM) or a flash memory store data in a power-off state, and program new data in a power-on state. Such non-volatile memory devices may be used in semiconductor products (e.g., a storage medium of mobile devices, a portable memory stick, etc).

Minimization of the semiconductor products has resulted in increased integration of the non-volatile memory devices used for such semiconductor products. As processing capacitance of the semiconductor products increases, non-volatile memory devices having a higher operation speed may be necessary.

Increased integration of the non-volatile memory devices has several drawbacks. For example, if short channel effects increase, then leakage current increases. The shorter the distance between adjacent memory cells, the greater the possibility of interference between the memory cells. Operational reliability of non-volatile memory devices decreases with increased leakage current and/or interference between memory cells.

### SUMMARY

Example embodiments relate to semiconductor devices and methods of fabricating the same. Other example embodiments relate to non-volatile memory devices for storing data and methods of fabricating the same.

Example embodiments provide a more highly integrated non-volatile memory device having increased operational reliability and methods of fabricating the same.

According to example embodiments, there is provided a non-volatile memory device including a semiconductor substrate having at least one pair of sidewall channel regions extending (for example, disposed) from the semiconductor substrate and opposite to each other, at least one floating gate electrode between the at least one pair of sidewall channel regions and protruding from the semiconductor substrate, and at least one control gate electrode formed (or disposed) on the semiconductor substrate and at least a portion of the at least one floating gate electrode.

The at least one pair of sidewall channel regions may be located within an active region of the semiconductor substrate. The active region may be defined (or provided) by a device isolation film formed in the semiconductor substrate. At least one surface of each sidewall channel region may contact the device isolation film. The active region may include a plurality of grooves. The at least one pair of sidewall channel regions may be defined (or established) by the device isolation film and the grooves.

The at least one floating gate electrode may include a recessed portion within the semiconductor substrate and opposite to the at least one pair of sidewall channel regions, and a protruding portion extending (for example, protruding upwardly) from the semiconductor substrate.

A tunneling insulating layer may be interposed between the at least one pair of sidewall channel regions and the recessed portion of the floating gate electrode. A blocking insulating layer may be interposed (or positioned) between the control gate electrodes and the protruding portion of the floating gate electrodes.

According to example embodiments, there is provided a non-volatile memory device including a semiconductor substrate having at least one pair of sidewall channel regions that extend (for example, are upwardly disposed) from the semiconductor substrate, at least one floating gate electrode between the at least one pair of the sidewall channel regions and protruding from the semiconductor substrate, and at least one control gate electrode formed (or disposed) on the semiconductor substrate and at least a portion of the floating gate electrode.

According to example embodiments, there is provided a method of fabricating a non-volatile memory device including forming at least one pair of sidewall channel regions in a semiconductor substrate. The at least one pair of sidewall channel regions may extend (for example, upwardly disposed) from the semiconductor substrate. The method may include forming at least one floating gate electrode that fills an area between the at least one pair of sidewall channel regions and protruding from the semiconductor substrate. At least one control gate electrode may be formed on the semiconductor substrate and at least a portion of the at least one floating gate electrode.

The method may include forming a device isolation film on the semiconductor substrate to establish an active region prior to forming the at least one floating gate electrode. Grooves may be formed within the active region. The at least one pair of sidewall channel regions may be defined (or established) in the active region by the grooves and the device isolation film.

### BRIEF DESCRIPTION OF THE DRAWINGS

Example embodiments will be more clearly understood from the following detailed description taken in conjunction with the accompanying drawings. FIGS. 1-9 represent non-limiting, example embodiments as described herein.

FIG. 1 is a diagram illustrating a perspective view of a non-volatile memory device according to example embodiments;

FIG. 2 is a diagram illustrating a cross-sectional view taken along line II-II′ of the non-volatile memory device shown in FIG. 1;

FIG. 3 is a diagram illustrating a cross-sectional view taken along line III-III′ of the non-volatile memory device shown in FIG. 1;

FIGS. 4 through 7 are diagrams illustrating perspective views of a method of fabricating a non-volatile memory device according to example embodiments;

FIG. 8 is a diagram illustrating a perspective view obtained from a simulation demonstrating operational characteristics of a non-volatile memory device according to example embodiments; and

FIG. 9 is a graph of the gate voltage (V_{g}) and current (I_{d}) obtained from a simulation of a non-volatile memory device according to example embodiments.

### DETAILED DESCRIPTION OF EXAMPLE EMBODIMENTS

Various example embodiments will now be described more fully with reference to the accompanying drawings in which some example embodiments are shown. In the drawings, the thicknesses of layers and regions may be exaggerated for clarity.

Detailed illustrative embodiments are disclosed herein. However, specific structural and functional details disclosed herein are merely representative for purposes of describing example embodiments. This invention may, however, may be embodied in many alternate forms and should not be construed as limited to only example embodiments set forth herein.

Accordingly, while example embodiments are capable of various modifications and alternative forms, embodiments thereof are shown by way of example in the drawings and will herein be described in detail. It should be understood, however, that there is no intent to limit example embodiments to the particular forms disclosed, but on the contrary, example embodiments are to cover all modifications, equivalents, and alternatives falling within the scope of example embodiments. Like numbers refer to like elements throughout the description of the figures.

It will be understood that, although the terms first, second, etc. may be used herein to describe various elements, these elements should not be limited by these terms. These terms are only used to distinguish one element from another. For example, a first element could be termed a second element, and, similarly, a second element could be termed a first element, without departing from the scope of example embodiments. As used herein, the term “and/or” includes any and all combinations of one or more of the associated listed items.

It will be understood that when an element is referred to as being “connected” or “coupled” to another element, it can be directly connected or coupled to the other element or intervening elements may be present. In contrast, when an element is referred to as being “directly connected” or “directly coupled” to another element, there are no intervening elements present. Other words used to describe the relationship between elements should be interpreted in a like fashion (e.g., “between” versus “directly between,” “adjacent” versus “directly adjacent,” etc.).

The terminology used herein is for the purpose of describing particular embodiments only and is not intended to be limiting of example embodiments. As used herein, the singular forms “a,” “an” and “the” are intended to include the plural forms as well, unless the context clearly indicates otherwise. It will be further understood that the terms “comprises,” “comprising,” “includes” and/or “including,” when used herein, specify the presence of stated features, integers, steps, operations, elements and/or components, but do not preclude the presence or addition of one or more other features, integers, steps, operations, elements, components and/or groups thereof.

It will be understood that, although the terms first, second, third etc. may be used herein to describe various elements, components, regions, layers and/or sections, these elements, components, regions, layers and/or sections should not be limited by these terms. These terms are only used to distinguish one element, component, region, layer or section from another region, layer or section. Thus, a first element, component, region, layer or section discussed below could be termed a second element, component, region, layer or section without departing from the scope of example embodiments.

Spatially relative terms, such as “beneath,” “below,” “lower,” “above,” “upper” and the like, may be used herein for ease of description to describe one element or a relationship between a feature and another element or feature as illustrated in the figures. It will be understood that the spatially relative terms are intended to encompass different orientations of the device in use or operation in addition to the orientation depicted in the Figures. For example, if the device in the figures is turned over, elements described as “below” or “beneath” other elements or features would then be oriented “above” the other elements or features. Thus, for example, the term “below” can encompass both an orientation which is above as well as below. The device may be otherwise oriented (rotated 90 degrees or viewed or referenced at other orientations) and the spatially relative descriptors used herein should be interpreted accordingly.

Example embodiments are described herein with reference to cross-sectional illustrations that are schematic illustrations of idealized embodiments (and intermediate structures). As such, variations from the shapes of the illustrations as a result, for example, of manufacturing techniques and/or tolerances, may be expected. Thus, example embodiments should not be construed as limited to the particular shapes of regions illustrated herein but may include deviations in shapes that result, for example, from manufacturing. For example, an implanted region illustrated as a rectangle may have rounded or curved features and/or a gradient (e.g., of implant concentration) at its edges rather than an abrupt change from an implanted region to a non-implanted region. Likewise, a buried region formed by implantation may result in some implantation in the region between the buried region and the surface through which the implantation may take place. Thus, the regions illustrated in the figures are schematic in nature and their shapes do not necessarily illustrate the actual shape of a region of a device and do not limit the scope.

It should also be noted that in some alternative implementations, the functions/acts noted may occur out of the order noted in the figures. For example, two figures shown in succession may in fact be executed substantially concurrently or may sometimes be executed in the reverse order, depending upon the functionality/acts involved.

Unless otherwise defined, all terms (including technical and scientific terms) used herein have the same meaning as commonly understood by one of ordinary skill in the art to which example embodiments belong. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

In order to more specifically describe example embodiments, various aspects will be described in detail with reference to the attached drawings. However, the present invention is not limited to example embodiments described.

Example embodiments relate to semiconductor devices and methods of fabricating the same. Other example embodiments relate to non-volatile memory devices for storing data and methods of fabricating the same.

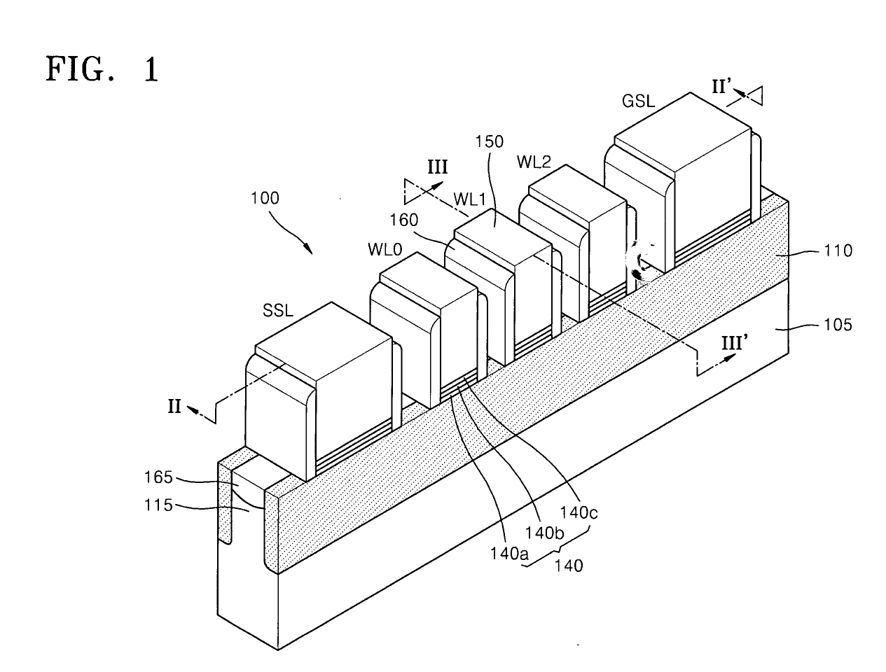

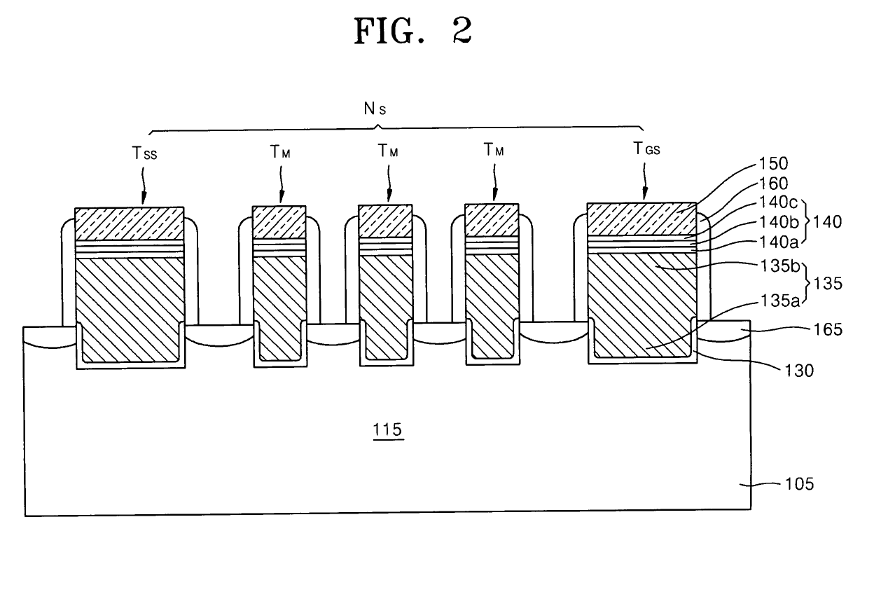

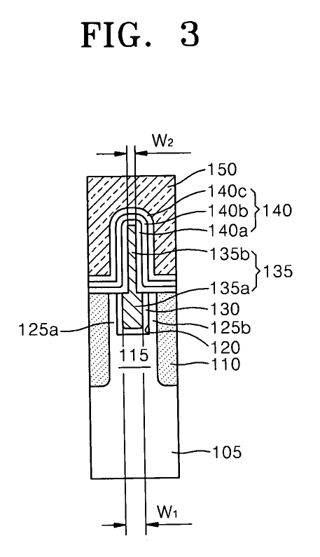

FIG. 1 is a diagram illustrating a perspective view of a non-volatile memory device 100 according example embodiments. FIG. 2 is a diagram illustrating a cross-sectional view taken along line II-II′ of the non-volatile memory device 100 shown in FIG. 1. FIG. 3 is a diagram illustrating a cross-sectional view taken along line III-III′ of the non-volatile memory device shown in FIG. 1.

Referring to FIGS. 1 to 3, a semiconductor substrate 105 may include an active region 115 established by a device isolation film 110. The semiconductor substrate 105 may include a bulk-type or a thin film-type semiconductor material (e.g., silicon, germanium, silicon-germanium or the like). The active region 115 establishes a portion where an active device may be formed. The device isolation film 110 may electrically separate active devices. The device isolation film 110 includes an appropriate insulating layer (e.g., an oxide film and/or a nitride film) (not shown).

The non-volatile memory device 100 may have a NAND structure. The active region 115 may denote at least one of a plurality of NAND strings Ns. A plurality of memory transistors T_{M}, a string select transistor T_{SS} and/or a ground select transistor T_{GS} may be formed (or disposed) in a NAND string N_{S}. The plurality of NAND strings may be established by the device isolation film 110.

At least one pair of sidewall channel regions 125a and 125b may be formed (or located) within the active region 115. The memory transistors T_{M}, the string select transistor T_{SS} and/or the ground select transistor T_{GS} may include at least one pair of sidewall channel regions 125a and 125b.

If the memory transistors T_{M}, the string select transistors T_{SS} and/or the ground select transistors T_{GS} are turned on, the pair of sidewall channel regions 125a and 125b may establish a conduction path of charges. By increasing the height of the pair of the sidewall channel regions 125a and 125b, a higher operation current may be provided to the non-volatile memory device 100, increasing the operating speed of the non-volatile memory device 100.

The sidewall channel regions 125a and 125b may be formed (or disposed) upward and opposite to each other on the semiconductor substrate 105. The active region 115 may include a plurality of grooves 120 in the active region 115. The sidewall channel regions 125a and 125b may be established by the groove 120 and the device isolation film 110. One side of each of the sidewall channel regions 125a and 125b contacts the device isolation film 110. The other side of each of the sidewall channel regions 125a and 125b contacts the groove 120. The sidewall channel regions 125a and 125b may have a thin plate shape. The sidewall channel regions 125a and 125b may form a thin body structure that may decrease a leakage current in the sidewall channel regions 125a and 125b. The sidewall channel regions 125a and 125b may be curvilinearly formed (or disposed) such that a channel length increases. As such, the short channel effects may be reduced (or prevented), decreasing the leakage current in the sidewall channel regions 125a and 125b.

At least one of floating gate electrode 135 fill the area between the sidewall channel regions 125a and 125b. The plurality of floating gate electrodes 135 may protrude (or extend) from the semiconductor substrate 105. Each of the floating gate electrodes 135 may include a recessed portion 135a and a protruding portion 135b. The recessed portion 135a may be filled within the groove 120 so as to face the sidewall channel regions 125a and 125b. The protruding portion 135b may extend upward from the recessed portion 135a so as to protrude from the semiconductor substrate 105. The floating gate electrode 135 may store charges. The floating gate electrode 135 may include an appropriate conductive layer (e.g., polysilicon or a metal) (not shown).

A width w₂ of the protruding portion 135b may be less than a width w₁ of the recessed portion 135a. The width w₁ of the recessed portion 135a may be enlarged to increase a quantity of stored charges. The width w₂ of the protruding portion 135b may be less than the width w₁ of the recessed portion 135a to reduce a parasitic coupling of the floating gate electrodes 135 between adjacent memory transistors T_{M}. If the parasitic coupling of the floating gate electrodes 135 between adjacent memory transistors T_{M} is reduce, data interference between the memory transistors T_{M} may decrease. The width w₂ of the protruding portion 135b ranges from one-third to two-thirds of the width w₁ of the recessed portion 135a.

At least one of control gate electrode 150 may be formed (or disposed) on the semiconductor substrate 105 and a portion of the floating gate electrode 135. The control gate electrode 150 may be formed on (or covering) the protruding portions 135b. The control gate electrode 150 may be formed (or traverse) on the sidewall channel regions 125a and 125b. Because the control gate electrode 150 is formed on the protruding portions 135b, a coupling ratio between the control gate electrode 150 and the floating gate electrode 135 may increase. As such, a control efficiency of the memory transistors T_{M} by the control gate electrodes 150 may increase.

The control gate electrodes 150 may be formed (or disposed) in a NAND structure. The control gate electrodes 150 may form a portion of a string select line SSL, word lines WL0, WL1 and WL2 and/or a ground select line GSL. The number of word lines WL0, WL1 and WL2 may vary. A tunneling insulating layer 130 may be interposed between the floating gate electrode 135 and the sidewall channel regions 125a and 125b. The tunneling insulating layer 130 may be formed on an inner surface of the groove 120 between the recessed portion 135a and the sidewall channel regions 125a and 125b.

A blocking insulating layer 140 may be interposed between the control gate electrode 150 and the protruding portion 135b of the floating gate electrode 135. The blocking insulating layer 140 may be interposed between the protruding portion 135b and the control gate electrode 150. The blocking insulating layer 140 may have an oxide-nitride-oxide (ONO) structure of stacking (e.g., a first oxide layer 140a, a nitride layer 140b and a second oxide layer 140c). The blocking insulating layer 140 may include a single insulating layer.

A pair of spacer insulating layers 160 may be formed (or disposed) on sidewalls of the control gate electrodes 150. Source/drain regions 165 may be establish in the active region 115 between the control gate electrodes 150. The source/drain regions 165 may be located along both ends of the sidewall channel regions 125a and 125b to connect the sidewall channel regions 125a and 125b of adjacent gate electrodes 150.

The source/drain regions 165 may be formed by doping impurities of an opposite type to that of the semiconductor substrate 105. If the semiconductor substrate 105 has a first conductivity type, the source/drain regions 165 may have a second conductivity type. The source/drain regions 165 may be formed by an electrical field effect due to a fringing field of the control gate electrodes 150.

As described above, the sidewall channel regions 125a and 125b may provide a higher operation current, increasing an operating speed of the non-volatile memory device 100. The sidewall channel regions 125a and 125b may form a thin body structure, increasing the channel length. As such, the leakage current of the non-volatile memory device 100 may decrease, increasing the operational reliability of the non-volatile memory device 100.

The formation of channels in other areas of the active region 115, except for the sidewall channel regions 125a and 125b, may be inhibited in order to increase efficiency of the thin body structure. A doping density of the impurities in the active region 115 under the floating gate electrode 135 may be greater than the doping density of the impurities in the sidewall channel regions 125a and 125b. Formation of the channels in the active region 115 under the floating gate electrode 135 may be reduced (or prevented). A thick buried insulating film (not shown) may be formed between a bottom surface of the groove 120 and the recessed portion 135a.

The structure of the non-volatile memory device 100 is not limited to the NAND structure shown in FIG. 1. The non-volatile memory device 100 may have a NOR structure or an AND structure. The memory transistors T_{M} having the NAND structure may be modified into the NOR structure or AND structure.

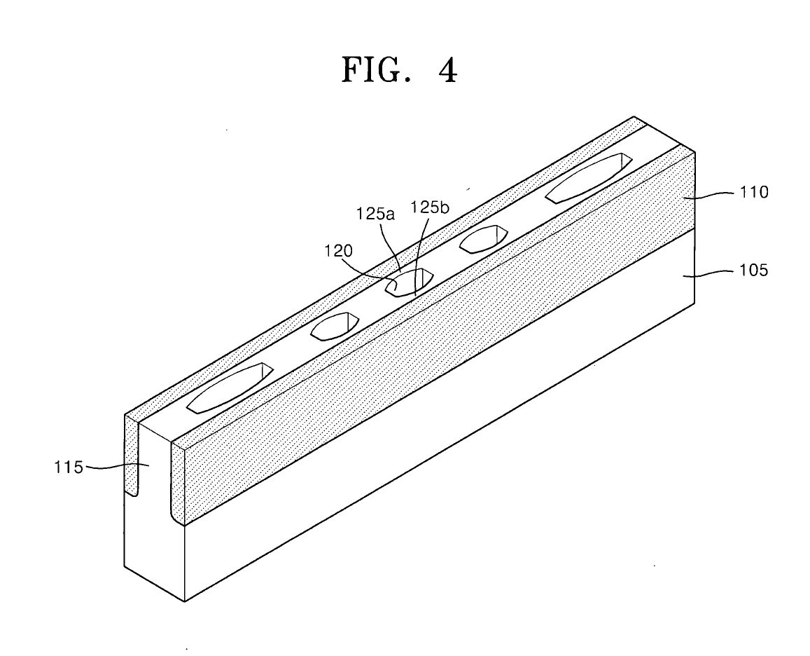

FIGS. 4 through 7 are diagrams illustrating perspective views of a method of fabricating a non-volatile memory device according to example embodiments.

Referring to FIG. 4, at least one pair of sidewall channel regions 125a and 125b may be established in a semiconductor substrate 105. A device isolation film 110 may be formed in the semiconductor substrate 105 to establish an active region 115. The device isolation film 110 may be formed in a trench (not shown) on the semiconductor substrate 105. The device isolation film 110 may have a shallow trench isolation (STI) structure. However, example embodiments are not limited thereto.

A plurality of grooves 120 may be formed in the active region 115 to establish the sidewall channel regions 125a and 125b between the device isolation film 110 and the grooves 120. A cross-section of the grooves 120 may have a circular, elliptical or polygonal shape. The grooves 120 may be formed by conventional lithography and etching.

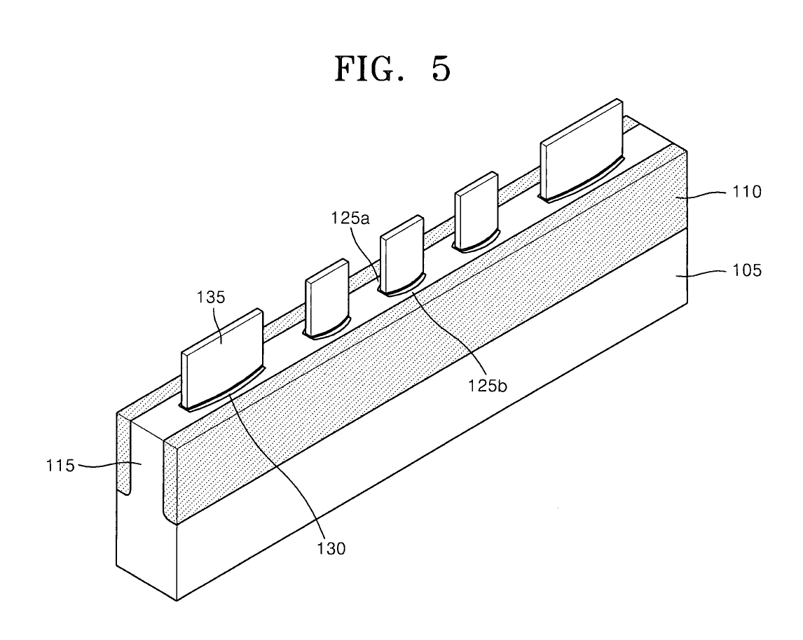

Referring to FIG. 5, a tunneling insulating layer 130 may be formed on side and bottom surfaces of the grooves 120 by thermally oxidizing the side and bottom surfaces of the grooves 120. The tunneling insulating layer 130 may be formed using chemical vapor deposition (CVD).

A floating gate electrode 135 may be formed in the grooves 120 and protruding from the semiconductor substrate 105. A conductive layer (not shown) may be formed on the tunneling insulating layer 130 in the grooves 120. The conductive layer may be patterned to form the floating gate electrodes 135.

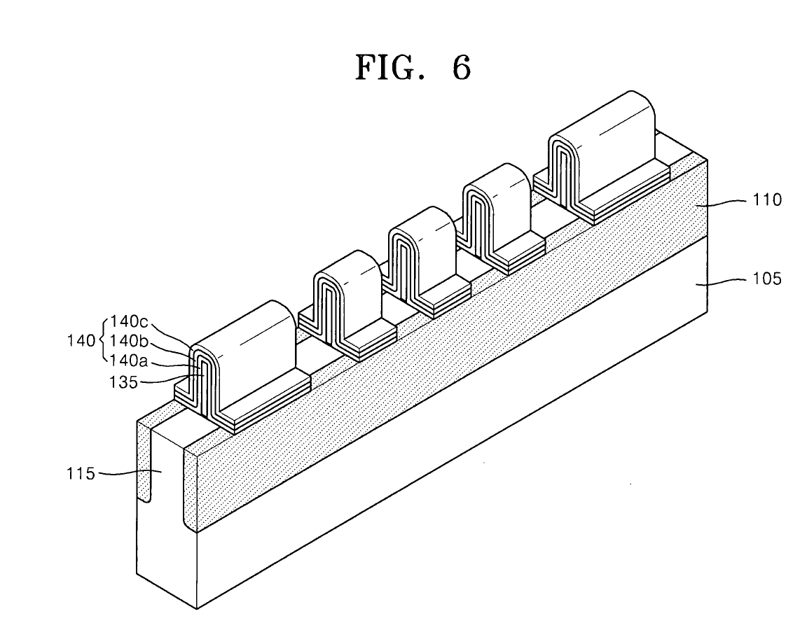

Referring to FIG. 6, a blocking insulating layer 140 may be formed on the semiconductor substrate 105 and the floating gate electrode 135. The blocking insulating layer 140 may include a first oxide layer 140a, a nitride layer 140b and a second oxide layer 140c sequentially formed on the floating gate electrode 135. The floating gate electrode 135 may be patterned to form the blocking insulating layer 140. The structure of the blocking insulating layer 140 may vary according to use.

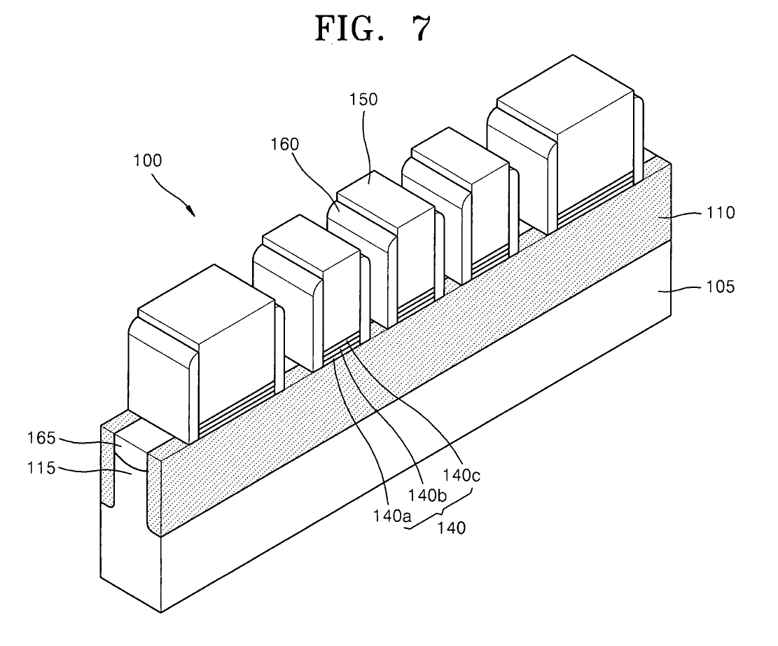

Referring to FIG. 7, a control gate electrode 150 may be formed on (or covering) the blocking insulating layer 140. A conductive layer (not shown) may be formed on the blocking insulating layer 140 and patterned to form the control gate electrode 150.

A pair of spacer insulating layers 160 may be formed on sidewalls of the control gate electrode 150. Forming the spacer insulating layer 160 may include forming an insulating layer formed on the control gate electrode 150 and anisotropically etching to form the spacer insulating layers 160.

Source/drain regions 165 may be established in the active region 115 between to the control gate electrodes 150. Forming the source/drain regions 165 may include doping the active region 115 with impurities of a second conductivity type (wherein the semiconductor substrate 105 includes impurities of a first conductivity type) to establish the source/drain regions 165. The source/drain regions 165 may be established by an electrical field effect without doping the impurities of the second conductivity type into the active region 115.

The method of fabricating the non-volatile memory device described with reference to FIGS. 4 through 7 may be used to fabricate a non-volatile memory device having a NOR structure or an AND structure.

FIG. 8 is a diagram illustrating a perspective view obtained from a simulation demonstrating operational characteristics of the non-volatile memory device according example embodiments.

In FIG. 8, the simulation was obtained using a non-volatile memory device 100 similar to that shown in FIG. 1. An operating voltage was supplied to the string select line SSL and the ground select line GSL. A pass voltage was supplied to the two word lines WL1 and WL2. A sweep voltage from 0 V to 6 V was supplied to the single word line WL0.

Referring to FIG. 8, the channels formed in the sidewall channel regions may be displayed by a bright color that denotes a high electron density. As such, the sidewall channel regions may be used as a conduction path.

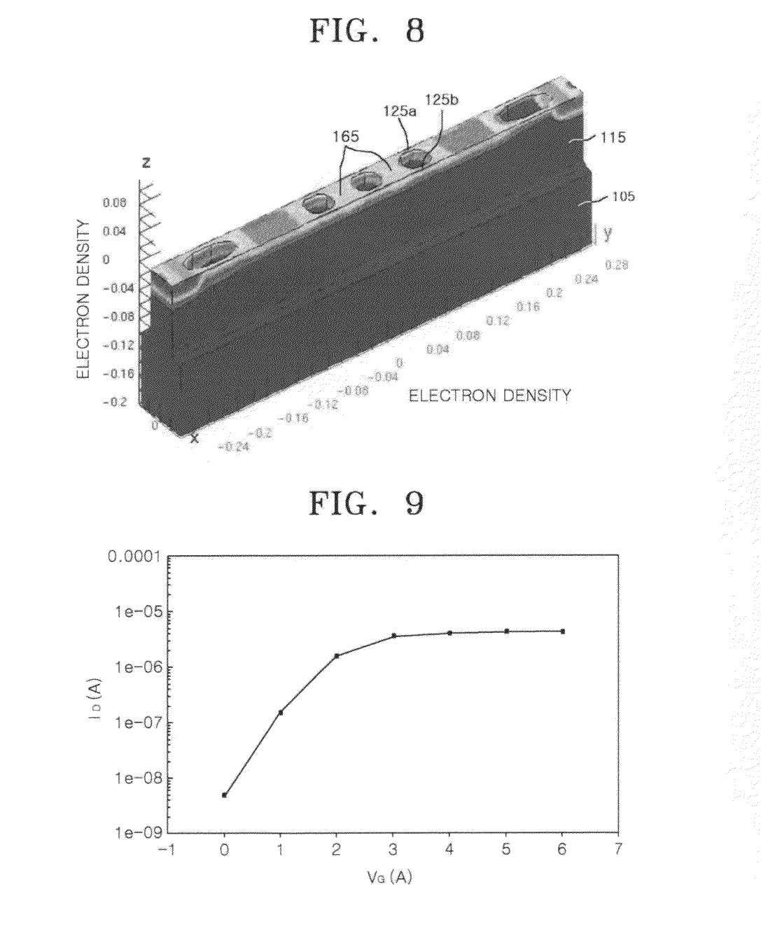

FIG. 9 is a graph of the gate voltage (V_{g}) and current (I_{d}) obtained from a simulation of a non-volatile memory device according to example embodiments.

Referring to FIG. 9, as a voltage V_{G} supplied to the word line WL0 increases, a current ID flows through the sidewall channel regions. The non-volatile memory device may have more operable reliability using the sidewall channel regions according to example embodiments.

In a non-volatile memory device according to example embodiments, sidewall channel regions may provide a higher operation current. As such, an operating speed of the non-volatile memory device may increase. The sidewall channel regions according to example embodiments may be used in a thin body structure having an increased channel length. As such, a leakage current of the non-volatile memory device may decrease, increasing an operational reliability of the non-volatile memory device.

The width of a protruding portion may be decreased such that a parasitic coupling of floating gate electrodes decreases. The possibility of data interference between memory transistors may decrease due to a reduction in the parasitic coupling. According to example embodiments, the control gate electrode may be formed on the wide surface of the protruding portion, increasing a coupling ratio of the floating gate electrode and the control gate electrode.

The foregoing is illustrative of example embodiments and is not to be construed as limiting thereof. Although a few example embodiments have been described, those skilled in the art will readily appreciate that many modifications are possible in example embodiments without materially departing from the novel teachings and advantages. Accordingly, all such modifications are intended to be included within the scope of example embodiments as defined in the claims. In the claims, means-plus-function clauses are intended to cover the structures described herein as performing the recited function, and not only structural equivalents but also equivalent structures. Therefore, it is to be understood that the foregoing is illustrative of various example embodiments and is not to be construed as limited to the specific embodiments disclosed, and that modifications to the disclosed embodiments, as well as other embodiments, are intended to be included within the scope of the appended claims.

1. A non-volatile memory device comprising:
a semiconductor substrate including a pair of sidewall channel regions upwardly disposed and opposite to each other;
a floating gate electrode that is filled between the pair of sidewall channel regions and protruding from the semiconductor substrate; and
a control gate electrode disposed on the semiconductor substrate to cover at least a portion of the floating gate electrode.

2. The non-volatile memory device of claim 1, wherein the pair of sidewall channel regions is located within an active region of the semiconductor substrate.

3. The non-volatile memory device of claim 2, wherein the active region is defined by a device isolation film formed in the semiconductor substrate, and one surface of each of the pair of sidewall channel regions contacts the device isolation film.

4. The non-volatile memory device of claim 2, wherein the active region comprises grooves therein, and the pair of sidewall channel regions is defined by the device isolation film and the grooves.

5. The non-volatile memory device of claim 2, wherein an impurity density of the active region under the floating gate electrode is higher than that of the pair of sidewall channel regions.

6. The non-volatile memory device of claim 1, wherein the floating gate electrode comprises a recessed portion located within the semiconductor substrate to be opposite to the pairs of sidewall channel regions, and a protruding portion extending from the recessed portion to protrude upwardly from the semiconductor substrate.

7. The non-volatile memory device of claim 6, wherein the width of the protruding portion of the floating gate electrode is narrower than that of the recessed portion of the floating gate electrode.

8. The non-volatile memory device of claim 6, wherein the control gate electrode covers the protruding portion of the floating gate electrode.

9. The non-volatile memory device of claim 7, further comprising a tunneling insulating layer interposed between the pair of sidewall channel regions and the floating gate electrode.

10. The non-volatile memory device of claim 9, wherein the tunneling insulating layer is interposed between the pair of sidewall channel regions and the recessed portion of the floating gate electrode.

11. The non-volatile memory device of claim 6, further comprising a blocking insulating layer interposed between the control gate electrode and the floating gate electrode.

12. The non-volatile memory device of claim 11, wherein the blocking insulating layer is interposed between the control gate electrodes and the extruding portion of the floating gate electrodes.

13. A non-volatile memory device comprising:
a semiconductor substrate including a plurality of pairs of sidewall channel regions that are upwardly disposed;
a plurality of floating gate electrodes that are filled between the pairs of the sidewall channel regions, and protruding from the semiconductor substrate; and
a plurality of control gate electrodes disposed on the semiconductor substrate to cover at least a portion of the floating gate electrodes.

14. The non-volatile memory device of claim 13, wherein the semiconductor substrate comprises an active region defined by a device isolation film, and the pairs of sidewall channel regions are disposed in the active region in a row.

15. The non-volatile memory device of claim 14, wherein the active region comprises a plurality of grooves, and the pairs of sidewall channel regions are defined by the device isolation film and the grooves.

16. The non-volatile memory device of claim 13, wherein each of the plurality of floating gate electrodes comprises a recessed portion located within the semiconductor substrate to be opposite to the pairs of sidewall channel regions, and a protruding portion extending from the recessed portion to protrude upwardly from the semiconductor substrate.

17. The non-volatile memory device of claim 16, wherein the width of the protruding portion of the floating gate electrodes is narrower than the recessed portion of the floating gate electrodes.

18. The non-volatile memory device of claim 13, wherein the control gate electrodes are arranged as a NAND structure.

19. A method of fabricating a non-volatile memory device comprising:
defining a plurality of pairs of sidewall channel regions in a semiconductor substrate, the pairs of sidewall channel regions upwardly disposed;
forming a plurality of floating gate electrodes that are filled between the pairs of sidewall channel regions, and protruding from the semiconductor substrate; and
forming a plurality of control gate electrodes on the semiconductor substrate to cover at least a portion of the floating gate electrodes.

20. The method of claim 19, before forming the floating gate electrodes, further comprising:
forming a device isolation film in the semiconductor substrate to define an active region; and
forming grooves within the active region,
wherein the pairs of sidewall channel regions are defined within the active region by the grooves and the device isolation film.

21. The method of claim 20, wherein each of the floating gate electrodes comprises a recessed portion that is filled in the grooves, and a protruding portion extending from the recessed portion to protrude upwardly from the semiconductor substrate.

22. The method of claim 21, wherein the width of the protruding portion of the floating gate electrodes is narrower than the width of the recessed portion of the floating gate electrodes.

23. The method of claim 21, before forming the floating gate electrodes, further comprising forming a plurality of tunnel insulating layers on an inner surface of the grooves.

24. The method of claim 21, before forming the control gate electrodes, further comprising forming a plurality of blocking insulating layers on the semiconductor substrate to cover the protruding portion of the floating gate electrodes.
